(19) United States
(12) Patent Application Publication
(10) Pub. No.: US 2014/0261677 A1
(43) Pub. Date: Sep. 18, 2014

(54) LAMINATED STRUCTURE AND LAMINATED STRUCTURE PRODUCTION METHOD

(71) Applicant: ASAHI GLASS COMPANY, LIMITED, Chiyoda-ku (JP)

(72) Inventors: Hiroshi SAKAMOTO, Tokyo (JP); Yasuhiro Ikeda, Tokyo (JP); Masanobu Isshiki, Tokyo (JP); Yuriko Kaida, Tokyo (JP)

(73) Assignee: ASAHI GLASS COMPANY, LIMITED, Chiyoda-ku (JP)

(21) Appl. No.: 14/291,633

(22) Filed: May 30, 2014

Related U.S. Application Data
(63) Continuation of application No. PCT/JP2012/081418, filed on Dec. 4, 2012.

(30) Foreign Application Priority Data
Dec. 8, 2011 (JP) 2011-269060

(51) Int. Cl. G02B 1/11; H01L 31/0224

(52) U.S. Cl. CPC G02B 1/11; H01L 31/022425
USPC 136/256; 359/601; 362/311.09; 264/1.7

(57) ABSTRACT

A laminated structure includes an anti-reflection structure having periodic concavo-convex parts on a surface thereof, and a transparent conductive layer formed on the concavo-convex parts. An arbitrary convex part, excluding a convex part located at an outermost side, and six convex parts having distances from the arbitrary convex part that amount to a smallest sum, are arranged to satisfy a condition requiring a connecting part to exist between the arbitrary convex part and each of four convex parts amongst the six convex parts, and a condition requiring a concave part to exist between the arbitrary convex part and each of two remaining convex parts amongst the six convex parts.

### CROSS-REFERENCE TO RELATED APPLICATIONS

This application is a continuation application filed under 35 U.S.C. 111(a) claiming the benefit under 35 U.S.C. 120 and 365(c) of a PCT International Application No. PCT/JP2012/081418 filed on Dec. 4, 2012 and designated the U.S., which is based upon and claims the benefit of priority of Japanese Patent Application No. 2011-269060 filed on Dec. 8, 2011, the entire contents of which are incorporated herein by reference.

### BACKGROUND OF THE INVENTION

1. Field of the Invention

The present invention relates to a laminated structure, and a laminated structure production method.

2. Description of the Related Art

Recently, an anti-reflection structure has been developed in which periodic concavo-convex parts are formed on a surface thereof, for use in solar cells, display devices such as an LCD (Liquid Crystal Display), and the like. An example of such an anti-reflection structure is proposed in International Publication No. WO 2011/027909 A1, for example. The anti-reflection structure may be the so-called moth eye type in which a pitch of the convex parts is less than or equal to a wavelength of visible light, so that reflectivity of light is reduced and transmittance of light is improved in a wide wavelength range. A laminated structure having a transparent conductive layer formed on the concavo-convex parts of the anti-reflection structure may be used in touchscreen panels or the like, for example. The touchscreen panel may be a resistive touchscreen panel using electrically resistive layers, or a capacitive touchscreen panel using electrostatic capacitance, for example.

The concavo-convex parts of the conventional anti-reflection structure include a large number of cone-shaped projections arranged in an array. In order to increase a filling rate of the projections, the projections are periodically arranged in a hexagonal lattice or a tetragonal lattice. In order to further increase the filling rate of the projections, the projections may be arranged so that lower parts of the projections overlap each other.

When the lower parts of the projections overlap each other, a height difference between a vertex of the convex part and a bottom of the concave part in the concavo-convex parts becomes small, and it may be difficult to obtain a sufficiently low reflectivity.

On the other hand, when the height difference between the vertex of the convex part and the bottom of the concave part in the concavo-convex parts is set large in order to obtain a sufficiently low reflectivity, a side surface of the projection becomes steep. Consequently, the transparent conductive layer formed on the side surface of the projection may become thin, to thereby reduce the conductivity. For this reason, in the conventional anti-reflection structure, it is difficult to simultaneously achieve low reflectivity and high conductivity.

### SUMMARY OF THE INVENTION

The present invention is conceived in view of the above described problem, and one object is to provide a laminated structure and a laminated structure production method, which can simultaneously achieve low reflectivity and high conductivity.

According to one aspect of the present invention, a laminated structure may include an anti-reflection structure having periodic concavo-convex parts on a surface thereof; and a transparent conductive layer formed on the concavo-convex parts, wherein an arbitrary convex part, excluding a convex part located at an outermost side, and six convex parts having distances from the arbitrary convex part that amount to a smallest sum, are arranged to satisfy conditions (1) and (2), wherein the condition (1) requires a connecting part to exist between the arbitrary convex part and each of four convex parts amongst the six convex parts, and wherein the condition (2) requires a concave part to exist between the arbitrary convex part and each of two remaining convex parts amongst the six convex parts.

According to another aspect of the present invention, a laminated structure production method may include producing an anti-reflection structure having periodic concavo-convex parts on a surface thereof, by using a die having periodic concavo-convex parts on a surface thereof; and forming a transparent conductive electrode on the concavo-convex parts of the anti-reflection structure, wherein an arbitrary convex part, excluding a convex part located at an outermost side, and six convex parts having distances from the arbitrary convex part that amount to a smallest sum, of the periodic concavo-convex parts of the die, are arranged to satisfy conditions (1) and (2), wherein the condition (1) requires a connecting part to exist between the arbitrary convex part and each of four convex parts amongst the six convex parts, and wherein the condition (2) requires a concave part to exist between the arbitrary convex part and each of two remaining convex parts amongst the six convex parts.

Other objects and further features of the present invention will be apparent from the following detailed description when read in conjunction with the accompanying drawings.

### BRIEF DESCRIPTION OF THE DRAWING

FIG. 1 is a perspective view illustrating a part of a laminated structure in a first embodiment of the present invention;

FIG. 2 is a perspective view illustrating an anti-reflection structure illustrated in FIG. 1;

FIGS. 3A and 3B are plan views schematically illustrating concavo-convex parts on a surface of the anti-reflection structure illustrated in FIG. 2;

FIGS. 4A, 4B, 4C, and 4D are diagrams illustrating the concavo-convex parts on the surface of the anti-reflection structure illustrated in FIG. 2;

FIGS. 5A and 5B are plan views schematically illustrating the concavo-convex parts on the surface of the anti-reflection structure illustrated in FIG. 2;

FIGS. 6A, 6B, and 6C are diagrams for explaining a production method for the anti-reflection structure in the first embodiment of the present invention;

FIGS. 7A, 7B, and 7C are diagrams for explaining the production method for the anti-reflection structure in the first embodiment of the present invention;

FIGS. 8A and 8B are plan views schematically illustrating concavo-convex parts on a surface of a die illustrated in FIGS. 6A through 6C;

FIGS. 9A and 9B are diagrams for explaining the production method for the anti-reflection structure in the first embodiment of the present invention;

FIG. 10 is a perspective view illustrating a part of a laminated structure in a second embodiment of the present invention;

FIG. 11 is a perspective view illustrating an anti-reflection structure illustrated in FIG. 10;

FIGS. 12A and 12B are plan views schematically illustrating concavo-convex parts on a surface of the anti-reflection structure illustrated in FIG. 11;

FIGS. 13A, 13B, and 13C are diagrams illustrating the concavo-convex parts on the surface of the anti-reflection structure illustrated in FIG. 11;

FIG. 14 is a cross sectional view illustrating an example of a display device using the laminated structure;

FIG. 15 is a cross sectional view illustrating an example of an illumination device using the laminated structure;

FIG. 16 is a cross sectional view illustrating an example of a solar cell using the laminated structure;

FIG. 17 is a diagram for explaining a method of creating an analyzing model in a first comparison example;

FIG. 18 is a diagram illustrating measured results of a surface resistivity in a practical example pe1 and a comparison example Cmp1; and

FIG. 19 is a diagram illustrating measured results of reflectivities in the practical example pe1 and the comparison example Cmp1.

### DESCRIPTION OF THE PREFERRED EMBODIMENTS

A description will hereinafter be given of embodiments of the present invention with reference to the drawings. In each of the figures, those parts that are the same are designated by the same reference numerals, and a description thereof will be omitted.

### First Embodiment

FIG. 1 is a perspective view illustrating a part of a laminated structure in a first embodiment of the present invention. In FIG. 1, contour lines are illustrated by thin solid lines, in order to represent concavo-convex parts on a surface of a laminated structure 2.

The laminated structure 2 illustrated in FIG. 1 includes an anti-reflection structure 10 having periodic concavo-convex parts 20 formed on a surface thereof, and a transparent conductive layer 30 formed on the concavo-convex parts 20. The transparent conductive layer 30 has a surface profile that follows a surface profile of the concavo-convex parts 20. A metal layer (not illustrated) may be formed between the concavo-convex parts 20 and the transparent conductive layer 30 in order to reduce resistance. A thickness of this metal layer may be 10 nm or less, from the standpoint of transmittance of light. The laminated structure 2 may be used in touchscreen panels or the like, including a resistive touchscreen panel using electrically resistive layers, and a capacitive touchscreen panel using electrostatic capacitance, for example.

FIG. 2 is a perspective view illustrating the anti-reflection structure illustrated in FIG. 1. In FIG. 2, contour lines are illustrated by thin solid lines, in order to represent concavo-convex parts on a surface of the anti-reflection structure 10. FIGS. 3A and 3B are plan views schematically illustrating the concavo-convex parts on the surface of the anti-reflection structure illustrated in FIG. 2. FIG. 3A illustrates an arrangement of lattices connecting vertexes of convex parts, and FIG. 3B illustrates a part of FIG. 3A. In FIGS. 3A and 3B, the convex parts and connecting parts are represented by different dot patterns in order to facilitate viewing of these figures, a vertex of the convex part is represented by a black circular mark “”, a bottom of a concave part is represented by a white circular mark “◯”, and the lattice connecting the vertexes of the convex parts is represented by a bold solid line “ [symbol] ”. FIGS. 4A, 4B, 4C, and 4D are diagrams illustrating the concavo-convex parts on the surface of the anti-reflection structure illustrated in FIG. 2. FIG. 4A illustrates a cross section of the concavo-convex parts along a line A-A in FIG. 3A, FIG. 4B illustrates a cross section of the concavo-convex parts along a line B-B in FIG. 3A, FIG. 4C illustrates a cross section of the concavo-convex parts along a line C-C in FIG. 3A, and FIG. 4D illustrates a cross section of the concavo-convex parts along a line D-D in FIG. 3A.

The anti-reflection structure 10 is the so-called moth eye type, and is formed by a base 12, and a resin layer 14 that is formed on the base 12, as illustrated in FIG. 2. The base 12 and the resin layer 14 may have translucency. The periodic concavo-convex parts 20 are formed on a surface of the resin layer 14. The anti-reflection structure 10 may be formed solely from the resin layer 14.

The base 12 is formed to a sheet shape, a plate shape, or a block shape, for example. A material used for the base 12 is not limited to a particular material. For example, glass, plastic, or the like may be used for the base 12.

For example, soda-lime glass, alkali-free glass, silica glass, or the like may be used for the glass. For example, the glass may be formed by the float method, the fusion method, or the like.

For example, a (metha)acrylic resin that is a copolymer of polymethyl methacrylate or methyl methacrylate and vinyl monomer such as another alkyl(metha)acrylate, styrene, or the like; a polycarbonate resin such as polycarbonate, diethylene glycol bisallyl carbonate (CR-39), or the like; a thermosetting (metha)acrylic resin such as a homopolymer or copolymer of (brominated) bisphenol-A di(metha)acrylate, an urethane degenerated monomer of a polymer or copolymer of (brominated) bisphenol-A mono(metha)acrylate, or the like; a polyester, particularly polyethylene terephthalate, polyethylene naphthalate, and unsaturated polyester; acryllonitril-styrene copolymer, polyvinyl chloride, polyurethane, epoxy resin, polyarylate, polyethersulfone, polyetherketone, cycloolefin polymer (product name: Arton manufactured by JSR Corporation, Zeonor manufactured by Zeon Cooperation), or the like may preferably be used for the plastic. In addition, aramide resins may also be used for the plastic by taking heat resistance into consideration.

For example, the resin layer 14 may be formed by coating a thermosetting or photopolymer resin on the base 12, and allowing the resin to cure (or harden). The concavo-convex parts 20 are formed on the surface of the resin layer 14.

As illustrated in FIG. 2 and FIGS. 3A and 3B, the concavo-convex parts 20 include convex parts 21, concave parts 22, and connecting parts 23. The connecting part 23 connects two convex parts 21 at a height position lower than a vertex 21a of the convex part 21 and higher than a bottom 22a of the concave part 22. The plurality of convex parts 21, the plurality of concave parts 22, and the plurality of connecting parts 23 are arranged two-dimensionally.

The convex parts 21 may be arranged periodically in a regular hexagonal lattice shape, quasi-hexagonal lattice shape, a regular tetragonal lattice shape, or a quasi-tetragonal lattice shape, for example. FIG. 2 and FIGS. 3A and 3B illustrate a case in which the convex parts 21 are arranged periodically in the regular hexagonal lattice shape. The convex parts 21 are preferably arranged periodically in the hexagonal lattice shape, in order to increase the plane filling rate of the convex parts 21. A description will hereunder be given for a case in which the convex parts 21 are periodically arranged in the hexagonal lattice shape. A case in which the convex parts 21 are periodically arranged in the tetragonal lattice shape will be described later in conjunction with a second embodiment.

The case in which “the convex parts 21 are periodically arranged in the regular hexagonal lattice shape” means that six (6) convex parts 21-2 through 21-7 having equal and shortest distance from an arbitrary convex part 21-1, excluding the convex part 21 located at an outermost side, are arranged in a periphery of the arbitrary convex part 21-1, as illustrated in FIG. 3B. The vertexes 21a of the six (6) convex parts 21-2 through 21-7 are arranged at equi-angular intervals (or pitch) of 60° with respect to the vertex 21a of the arbitrary convex part 21-1 located at a center of the six (6) convex parts 21-2 through 21-7, to form the regular hexagonal lattice shape.

The case in which “the convex parts 21 are periodically arranged in the quasi-hexagonal lattice shape” means that six (6) convex parts 21 are periodically arranged in a hexagonal lattice shape approximately conforming to the regular hexagonal lattice shape. The quasi-hexagonal lattice shape may have one or more lattices of the regular hexagonal lattice shape expanded in a predetermined direction or distorted. The distorted lattices of the regular hexagonal lattice shape may be continuously arranged in a linear shape, a curve shape, or a zigzag or wavy shape.

In this embodiment, the arbitrary convex part 21-1, excluding the convex part 21 located at the outermost side, and the six (6) convex parts 21-2 through 21-7 having the distances from the arbitrary convex part 21-1 that amount to a smallest sum, are arranged to satisfy the following conditions (1) and (2), as illustrated in FIGS. 3A and 3B.

Condition (1): The connecting part 23 exists between the arbitrary convex part 21-1 and each of four (4) convex parts 21-2, 21-3, 21-5, and 21-6 amongst the six (6) convex parts 21-2 through 21-7; and

Condition (2): The concave part 22 exists between the arbitrary convex part 21-1 and each of two (2) remaining convex parts 21-4 and 21-7 amongst the six (6) convex parts 21-2 through 21-7.

The “distance” between two convex parts 21 refers to a distance between the vertexes 21a of the two convex parts 21. In a case in which a plurality of combinations exist for the six (6) convex parts 21 having the distances from the arbitrary convex part 21-1 that amount to the smallest sum, the conditions (1) and (2) described above stand for each of such combinations. In this example, however, there is only one combination for the six (6) convex parts 21 having the distances from the arbitrary convex part 21-1 that amount to the smallest sum.

In the case in which the conditions (1) and (2) stand, amongst three (3) directions that intersect at the arbitrary convex part 21-1 illustrated in FIG. 3B located at the center, the convex part 21 and the connecting part 23 are alternately arranged along two directions (directions F1 and F2), and the convex part 21 and the concave part 22 are alternately arranged along the remaining one direction (direction F3). A pitch P1 illustrated in FIGS. 4A, 4B, and 4C with which the convex parts 21 are intermittently arranged in the directions F1, F2, and F3 may be set to a length that is less than or equal to the wavelength of visible light. A pitch P2 illustrated in FIG. 4C with which the convex parts 21 are intermittently arranged in a direction perpendicular to the direction F3 is greater than the pitch P1. The concave part 22 and the connecting part 23 are alternately arranged along a direction parallel to the direction F1, as illustrated in FIGS. 3A and 3B and FIG. 4D.

Accordingly, the direction in which the convex part 21 and the concave part 22 are alternately arranged, and the direction in which the convex part 21 and the connecting part 23 are alternately arranged, are different. For this reason, a height difference H1 illustrated in FIG. 4B between the vertex 21a of the convex part 21 and the bottom 22a of the concave part 22, and a height difference H2 illustrated in FIG. 4A between the vertex 21a of the convex part 21 and a predetermined part 23a of the connecting part 23 illustrated in FIG. 2, can be designed independently. In other words, the height difference H1 and the height difference H2 can be optimized independently. The predetermined part 23a of the connecting part 23 corresponds to a lowest part between the vertexes 21a of the convex parts 21, and corresponds to a highest part between the bottoms 22a of the concave parts 22.

The range of the pitch P1 may be set first in order to optimize the height difference H1 and the height difference H2. As described above, the pitch P1 is set to less than or equal to the wavelength of visible light, and may be 400 nm or less, for example, and may preferably be 300 nm or less. In addition, from the standpoint of productivity, the pitch P1 may be set to 50 nm or greater, for example, and may preferably be set to 100 nm or greater. Hence, the pitch P1 may be set in a range of 50 nm to 400 nm.

Next, a range of an aspect ratio of the concavo-convex parts 20 is set. The aspect ratio of the concavo-convex parts 20 is represented by a ratio H1/P1 of the height difference H1 between the vertex 21a of the convex part 21 and the bottom 22a of the concave part 22, and the pitch P1 of the convex parts 21. From the standpoint of low reflectivity of the anti-reflection structure 10, the aspect ratio H1/P1 may be 0.5 or greater, for example, and may preferably be 0.7 or greater, and may more preferably be 1 or greater. In addition, from the standpoint of productivity, the aspect ratio H1/P1 may be 4 or less, for example, and may preferably be 3 or less, and may more preferably be 2 or less. In a case in which the pitch of the convex parts 21 in the direction F1, the pitch of the convex parts 21 in the direction F2, and the pitch of the convex parts 21 in the direction F3 are different, the aspect ratio may be obtained from the shortest pitch. Because the aspect ratio H1/P1 is in a range of 0.5 to 4, the height difference H1 may be in a range of 100 nm to 500 nm, for example.

Next, a ratio H2/H1 of the height difference H1 and the height difference H2 is set. The larger the ratio H2/H1, the lower the height of the predetermined part 23a of the connecting part 23 becomes, and the more improved the low reflectivity of the anti-reflection structure 10 becomes. The ratio H2/H1 may be 0.1 or greater, for example, and may preferably be 0.2 or greater, and may more preferably be 0.3 or greater. On the other hand, the smaller the ratio H2/H1, the more gradual the inclination becomes between the vertex 21a of the convex part 21 and the predetermined part 23a of the connecting part 23, as will be described later in more detail, and the thicker the transparent conductive layer 30 becomes, to make it easier for the current to flow. The ratio H2/H1 may be 0.9 or less, for example, and may preferably be 0.7 or less, and may more preferably be 0.5 or less. Because the ratio H2/H1 is in a range of 0.1 to 0.9, the height difference H2 may be in a range of 30 nm to 300 nm, for example.

According to this embodiment, the height difference H1 and the height difference H2 can be optimized independently. For this reason, the aspect ratio H1/P1 and the ratio H2/H1 can be optimized independently, and it is possible to simultaneously achieve low reflectivity and high conductivity.

The pitch P1, the height difference H1, the height difference H2, and the like can be obtained from an AFM (Atomic Force Microscope) image picked up by an AFM before forming the transparent conductive layer 30, and a cross section profile of the AFM image.

In this embodiment, the convex part 21 and the connecting part 23 are alternately arranged in the direction F1 and the direction F2 which are linear directions, and the convex part 21 and the concave part 22 are alternately arranged in the direction F3 which is a linear direction. However, as long as the conditions (1) and (2) described above stand, the present invention is not limited to such arrangements. For example, in a case in which the hexagonal lattice is arranged in a curved shape, the convex part 21 and the connecting part 23 may be alternately arranged along a predetermined curved direction.

In this embodiment, attention is drawn to the arrangement of the convex parts 21, however, the attention may be drawn to the arrangement of the concave parts 22.

FIGS. 5A and 5B are plan views schematically illustrating the concavo-convex parts on the surface of the anti-reflection structure illustrated in FIG. 2. FIG. 5A illustrates an arrangement of lattices connecting the bottoms of the concave parts, and FIG. 5B illustrates a part of FIG. 5A. In FIGS. 5A and 5B, the convex parts 21 and connecting parts 23 are represented by different dot patterns in order to facilitate viewing of these figures, the vertex 21a of the convex part 21 is represented by a black circular mark “”, the bottom 22a of the concave part 22 is represented by a white circular mark “◯”, and the lattice connecting the bottoms 22a of the concave parts 22 is represented by a bold solid line “ [symbol] ”.

As illustrated in FIGS. 5A and 5B, the arbitrary concave part 22-1, excluding the concave part 22 located at the outermost side, and the six (6) concave parts 22-2 through 22-7 having the distances from the arbitrary concave part 22-1 that amount to a smallest sum, are arranged to satisfy the following conditions (3) and (4), as illustrated in FIGS. 5A and 5B.

Condition (3): The connecting part 23 exists between the arbitrary concave part 22-1 and each of four (4) concave parts 22-2, 22-3, 22-5, and 22-6 amongst the six (6) concave parts 22-2 through 22-7; and

Condition (4): The convex part 21 exists between the arbitrary concave part 22-1 and each of two (2) remaining concave parts 22-4 and 22-7 amongst the six (6) concave parts 22-2 through 22-7.

The “distance” between two concave parts 22 refers to a distance between the bottoms 22a of the two concave parts 22. In a case in which a plurality of combinations exist for the six (6) concave parts 22 having the distances from the arbitrary concave part 22-1 that amount to the smallest sum, the conditions (3) and (4) described above stand for each of such combinations. In this example, however, there is only one combination for the six (6) concave parts 22 having the distances from the arbitrary concave part 22-1 that amount to the smallest sum.

The transparent conductive layer 30 is formed on the concavo-convex parts 20 of the anti-reflection structure 10. The surface profile of the transparent conductive layer 30 follows the surface profile of the concavo-convex parts 20, and is approximately the same as the surface profile of the concavo-convex parts 20.

The thicker an average thickness of the transparent conductive layer 30, the higher the conductivity of the transparent conductive layer 30 becomes. However, when the average thickness of the transparent conductive layer 30 becomes excessively thick, the reflectivity of light may increase. For this reason, the average thickness of the transparent conductive layer 30 may be 10 nm to 150 nm, preferably 30 nm to 100 nm, and more preferably 50 nm to 80 nm.

The thickness of the transparent conductive layer 30 may be thicker at the part having the gradual inclination, and thinner at the part having the steep inclination. The thickness of the transparent conductive layer 30 may be the thickest at the vertex 21a of the convex part 21, and thinnest at the part between the vertex 21a of the convex part 21 and the bottom 22a of the concave part 22.

Between the vertex 21a of the convex part 21 and the bottom 22a of the concave part 22, the smaller the height difference H1 illustrated in FIG. 4B, the more gradual the inclination becomes and the thinner the thickness of the transparent conductive layer 30 becomes, to make it easier for the current to flow. On the other hand, when the height difference H1 is excessively small, it may be difficult to obtain a sufficiently low reflectivity.

The inclination is gradual at the predetermined part 23a of the connecting part 23, similarly as in the case of the vertex 21a of the convex part 21, and the transparent conductive layer 30 is thick at the predetermined part 23a. For this reason, the current easily flows in a net pattern along the direction F1 and the direction F2 in which the convex part 21 and the connecting part 23 are alternately arranged. Between the vertex 21a of the convex part 21 and the predetermined part 23a of the connecting part 23, the smaller the height difference H2 illustrated in FIG. 4A (that is, the smaller the ratio H2/H1), the more gradual the inclination becomes and the thicker the transparent conductive layer 30 becomes, to make it easier for the current to flow.

According to this embodiment, since the height difference H1 and the height difference H2 can be optimized independently as described above, it is possible to simultaneously achieve the low reflectivity and the high conductivity.

For example, the transparent conductive layer 30 may be made of a material such as ITO (In₂O₃—SnO₂: Indium Tin Oxide), SnO₂ (tin oxide), IZO (In₂O₃—ZnO: Indium Zinc Oxide), AZO (Aluminum-doped Zinc Oxide), FTO (Fluorine-doped Tin Oxide), GZO (Gallium-doped Zinc Oxide), or the like.

FIGS. 6A, 6B, and 6C and FIGS. 7A, 7B, and 7C are diagrams for explaining a production method for the anti-reflection structure in the first embodiment of the present invention. FIGS. 6A through 6C illustrate first step in which a stamper is produced using a die, and FIGS. 7A through 7C illustrate second step in which the anti-reflection structure (that is, a replica) is produced using the stamper.

The production method for the anti-reflection structure may include steps to produce the anti-reflection structure 10 having the periodic concavo-convex parts 20 formed on the surface thereof, using a die 50 having periodic concavo-convex parts 60 formed on a surface of the die 50. For example, these steps may include first step to produce a stamper 70 having concavo-convex parts 80 formed on a surface thereof by reversing and transferring the shape of the concavo-convex parts 60 of the die 50, and second step to produce the anti-reflection structure 10 having the concavo-convex parts 20 on the surface thereof by reversing and transferring the shape of the concavo-convex parts 80 of the stamper 70. The die 50 may be used repeatedly in the first step, and the stamper 70 may be used repeatedly in the second step.

For example, the first step may include step illustrated in FIG. 6A to prepare the die 50, step illustrated in FIG. 6B to produce the stamper 70 by forming a metal layer on the concavo-convex parts 60 of the die 50, and step illustrated in FIG. 6C to separate the stamper 70 from the die 50. For example, the stamper 70 may be made of a material such as nickel (Ni), or the like. For example, the stamper 70 may be formed by forming a conductive layer on the concavo-convex parts 60 of the die 50, and thereafter forming a metal layer made of Ni or the like by electroforming on the conductive layer. The conductive layer may be formed by a forming method such as electroless plating, PVD (Physical Vapor Deposition) including sputtering and vacuum deposition, or the like.

For example, the second step may include step illustrated in FIG. 7A to coat a curing resin on the base 12 to form a coated layer 13, step illustrated in FIG. 7B to cure the coated layer 13 in a state in which the concavo-convex parts 80 of the stamper 70 are pressed against a surface of the coated layer 13, and step illustrated in FIG. 7C to separate the stamper 70 from a resin layer 14 that is obtained by curing the coated layer 13. The curing resin may be a thermosetting resin or a photopolymer resin, for example. The curing resin may be coated by a general coating method such as spin-coating, die-coating, ink-jet coating, or the like.

The anti-reflection structure 10 is produced in the manner described above. The concavo-convex parts 20 of the anti-reflection structure 10 have a shape corresponding to a twice-reversed shape of the concavo-convex parts 60 of the die 50, and thus, the shape and size of the concavo-convex parts 20 of the anti-reflection structure 10 are approximately the same as those of the concavo-convex parts 60 of the die 50.

FIGS. 8A and 8B are plan views schematically illustrating concavo-convex parts on the surface of the die illustrated in FIGS. 6A through 6C. FIG. 6A illustrates an arrangement of lattices connecting vertexes of convex parts, and FIG. 8B illustrates a part of FIG. 8A. In FIGS. 8A and 8B, the convex parts and connecting parts are represented by different dot patterns in order to facilitate viewing of these figures, a vertex of the convex part is represented by a black circular mark “”, a bottom of a concave part is represented by a white circular mark “◯”, and the lattice connecting the vertexes of the convex parts is represented by a bold solid line “ [symbol] ”.

The concavo-convex parts 60 of the die 50 may include convex parts 61, concave parts 62, and connecting parts 63, similarly to the concavo-convex parts 20 of the anti-reflection structure 10. The connecting part 63 connects two convex parts 61 at a height position lower than a vertex 61a of the convex part 61 and higher than a bottom 62a of the concave part 62. The plurality of convex parts 61, the plurality of concave parts 62, and the plurality of connecting parts 63 are arranged two-dimensionally.

The convex parts 61 may be arranged periodically in a regular hexagonal lattice shape, quasi-hexagonal lattice shape, a regular tetragonal lattice shape, or a quasi-tetragonal lattice shape, for example. In this embodiment, the convex parts 61 are arranged periodically in the regular hexagonal lattice shape. The convex parts 61 are preferably arranged periodically in the hexagonal lattice shape, in order to increase the plane filling rate of the convex parts 61.

In a case in which the convex parts 61 are periodically arranged in the regular hexagonal lattice shape, six (6) convex parts 61-2 through 61-7 having equal and shortest distance from an arbitrary convex part 61-1, excluding the convex part 61 located at an outermost side, are arranged in a periphery of the arbitrary convex part 61-1. The vertexes 61a of the six (6) convex parts 61-2 through 61-7 are arranged at equi-angular intervals (or pitch) of 60° with respect to the vertex 61a of the arbitrary convex part 61-1 located at a center of the six (6) convex parts 61-2 through 61-7, to form the regular hexagonal lattice shape.

In this embodiment, the arbitrary convex part 61-1, excluding the convex part 61 located at the outermost side, and the six (6) convex parts 61-2 through 61-7 having the distances from the arbitrary convex part 61-1 that amount to a smallest sum, are arranged to satisfy the following conditions (5) and (6), as illustrated in FIGS. 8A and 8B.

Condition (5): The connecting part 63 exists between the arbitrary convex part 61-1 and each of four (4) convex parts 61-2, 61-3, 61-5, and 61-6 amongst the six (6) convex parts 61-2 through 61-7; and

Condition (6): The concave part 62 exists between the arbitrary convex part 61-1 and each of two (2) remaining convex parts 61-4 and 61-7 amongst the six (6) convex parts 61-2 through 61-7.

In this example, there is only one combination for the six (6) convex parts 61 having the distances from the arbitrary convex part 61-1 that amount to the smallest sum.

In the case in which the conditions (5) and (6) stand, amongst three (3) directions that intersect at the arbitrary convex part 61-1 illustrated in FIG. 8B located at the center, the convex part 61 and the connecting part 63 are alternately arranged along two directions (directions F1 and F2), and the convex part 61 and the concave part 62 are alternately arranged along the remaining one direction (direction F3). The concave part 62 and the connecting part 63 are alternately arranged along a direction parallel to the direction F1.

Accordingly, the direction in which the convex part 61 and the concave part 62 are alternately arranged, and the direction in which the convex part 61 and the connecting part 63 are alternately arranged, are different. For this reason, a height difference between the vertex 61a of the convex part 61 and the bottom 62a of the concave part 62, and a height difference between the vertex 61a of the convex part 61 and a predetermined part of the connecting part 63 (corresponding to the predetermined part 23a of the connecting part 23 of the anti-reflection structure 10) can be designed independently. In other words, the height difference H1 between the vertex 21a of the convex part 21 and the bottom 22a of the concave part 22, and the height difference H2 between the vertex 21a of the convex part 21 and the predetermined part 23a of the connecting part 23 can be optimized independently in the anti-reflection structure 10 illustrated in FIGS. 2 through 5B. Because the height difference H1 and the height difference H2 can be optimized independently, it is possible to simultaneously achieve low reflectivity and high mar resistance.

In this embodiment, the concavo-convex parts 20 of the anti-reflection structure 10 have the shape corresponding to the twice-reversed shape of the concavo-convex parts 60 of the die 50. However, the shape of the concavo-convex parts 20 of the anti-reflection structure 10 may correspond to a shape of the concavo-convex parts 60 of the die 50 that is reversed one or more times. In addition, the coated layer 13 illustrated in FIG. 7B may be cured in a state in which the concavo-convex parts 60 of the die 50 are pressed against the coated layer 13. Because the conditions (1) and (2) described above are satisfied regardless of the number of times the shape of the concavo-convex parts 60 of the die 50 is reversed, it is possible to simultaneously achieve the low reflectivity and the high mar resistance.

The production method for the laminated structure may further include step (not illustrated) to form the transparent conductive layer 30 on the concavo-convex parts 20 of the anti-reflection structure 10. For example, the transparent conductive layer 30 may be formed by a forming method such as CVD (Chemical Vapor Deposition) including thermal CVD, plasma CVD and photo CVD, PVD (Physical Vapor Deposition) including vacuum deposition, plasma deposition and sputtering, or the like.

FIGS. 9A and 9B are diagrams for explaining the production method for the anti-reflection structure in the first embodiment of the present invention. FIGS. 9A and 9B illustrate steps of producing the die 50.

The production method for the laminated structure may further include the steps of producing the die 50. For example, these steps may include step to form a resist layer 52 on a base 51 illustrated in FIG. 6A, step illustrated in FIG. 9A to expose on a surface of the resist layer 52 first interference fringes having a light intensity that changes in a first direction (direction G1), step illustrated in FIG. 9B to expose on the surface of the resist layer 52 second interference fringes having a light intensity that changes in a second direction (direction G2) intersecting the first direction, and step to develop the resist layer 52 after exposing the first and second interference fringes.

For example, the base 51 illustrated in FIG. 6A may be formed to a sheet shape, a plate shape, a block shape, or a roll shape. A material used for the base 51 is not limited to a particular material. For example, silicon, silica glass, soda-lime glass, alkali-free glass, or the like may be used for the base 51.

A material used for the resist layer 52 may include both negative type and positive type resists that are generally used in the art. A developing agent (or developer) may be selected depending on the material used for the resist layer 52.

The first interference fringes may be formed by two-beam interference exposure. A plurality of exposed parts 53 that are exposed by the first interference fringes are arranged at intervals along the first direction (direction G1). A general laser oscillator, such as a He—Cd laser (wavelength of 325 nm) may be used as a light source of the interference waves.

The second interference fringes may be formed by two-beam interference exposure, in a manner similar to the first interference fringes, after rotating the resist layer 52. A plurality of exposed parts 54 that are exposed by the second interference fringes are arranged at intervals along the second direction (direction G2).

In this embodiment, the exposure of the first interference fringes and the exposure of the second interference fringes are carried out separately. However, the exposure of the first interference fringes and the exposure of the second interference fringes may be carried out simultaneously.

The resist layer 52 is developed after exposing the first and second interference fringes. A resin layer 56 illustrated in FIG. 6A having the periodic concavo-convex parts 60 on a surface thereof can be obtained by developing the resist layer 52.

In a case in which a negative type resist is used for the resist layer 52, the higher the intensity of exposure at a certain part the more likely this certain part will remain after the developing. For this reason, an intersecting part 55 of an exposed part 53 and an exposed part 54 illustrated in FIG. 9B becomes the convex part 61 after the developing. The convex part 61 is formed in a narrowing shape towards its vertex 61a. Parts other than the intersecting part 53 of the exposed parts 53 and 54 become the connecting parts 63 after the developing.

On the other hand, in a case in which a positive type resist is used for the resist layer 52, the higher the intensity of exposure at a certain part the more likely this certain part will be removed after the developing. For this reason, the intersecting part 55 of the exposed part 53 and the exposed part 54 illustrated in FIG. 9B becomes the concave part 62 after the developing. The concave part 62 is formed in a narrowing shape towards its bottom 62a. Parts other than the intersecting part 53 of the exposed parts 53 and 54 become the connecting parts 63 after the developing.

The die 50 may be produced in the manner described above. In a case in which an angle θ formed by the first direction and the second direction is 60°, the convex parts 61 are periodically arranged in the regular hexagonal lattice shape. In a case in which the angle θ formed by the first direction and the second direction is 90°, the convex parts 61 are periodically arranged in the regular tetragonal lattice shape.

In this embodiment, the die 50 is produced by exposing interference fringes on the resist layer 52 by the two-beam interference exposure. However, the method of producing the die 50 is not limited to such a method. For example, the concavo-convex parts 60 may be formed on the surface of the base 51 by other methods such as photolithography, EB (Electron Beam) lithography, laser lithography, or the like.

### Second Embodiment

FIG. 10 is a perspective view illustrating a part of a laminated structure in a second embodiment of the present invention. In FIG. 10, contour lines are illustrated by thin solid lines, in order to represent concavo-convex parts on a surface of a laminated structure 102.

The laminated structure 102 illustrated in FIG. 10 includes an anti-reflection structure 110 having periodic concavo-convex parts 120 formed on a surface thereof, and a transparent conductive layer 130 formed on the concavo-convex parts 120, similarly to the laminated structure 2 illustrated in FIG. 2. The transparent conductive layer 130 has a surface profile that follows a surface profile of the concavo-convex parts 120. A metal layer (not illustrated) may be formed between the concavo-convex parts 120 and the transparent conductive layer 130 in order to reduce resistance.

The anti-reflection structure 110 is the so-called moth eye type, and is formed by a base 112, and a resin layer 114 that is formed on the base 112, similarly to the anti-reflection structure 10 illustrated in FIG. 2. The periodic concavo-convex parts 120 are formed on a surface of the resin layer 114. The anti-reflection structure 110 may be formed solely from the resin layer 114.

FIG. 11 is a perspective view illustrating the anti-reflection structure illustrated in FIG. 10. In FIG. 11, contour lines are illustrated by thin solid lines, in order to represent concavo-convex parts on a surface of the anti-reflection structure 110. FIGS. 12A and 12B are plan views schematically illustrating the concavo-convex parts on the surface of the anti-reflection structure illustrated in FIG. 11. FIG. 12A illustrates an arrangement of lattices connecting vertexes of convex parts, and FIG. 12B illustrates a part of FIG. 12A. In FIGS. 12A and 12B, the convex parts and connecting parts are represented by different dot patterns in order to facilitate viewing of these figures, the vertex of the convex part is represented by a black circular mark “”, a bottom of a concave part is represented by a white circular mark “◯”, and the lattice connecting the vertexes of the convex parts is represented by a bold solid line “ [symbol] ”. FIGS. 13A, 13B, and 13C are diagrams illustrating the concavo-convex parts on the surface of the anti-reflection structure illustrated in FIG. 11. FIG. 13A illustrates a cross section of the concavo-convex parts along a line A-A in FIG. 12A, FIG. 13B illustrates a cross section of the concavo-convex parts along a line B-B in FIG. 12A, and FIG. 13C illustrates a cross section of the concavo-convex parts along a line C-C in FIG. 12A.

The anti-reflection structure 110 is the so-called moth eye type, and is formed by a base 112, and a resin layer 114 that is formed on the base 112, as illustrated in FIG. 11, similarly to the first embodiment. The periodic concavo-convex parts 120 are formed on a surface of the resin layer 114.

The concavo-convex parts 120 include convex parts 121, concave parts 122, and connecting parts 123. The connecting part 123 connects two convex parts 121 at a height position lower than a vertex 121a of the convex part 121 and higher than a bottom 122a of the concave part 122. The plurality of convex parts 121, the plurality of concave parts 122, and the plurality of connecting parts 123 are arranged two-dimensionally.

The convex parts 121 may be arranged periodically in a regular tetragonal lattice shape, for example. The case in which “the convex parts 121 are periodically arranged in the regular tetragonal lattice shape” means that four (4) convex parts 121 having equal and shortest distance from an arbitrary concave part 122, excluding the concave part 122 located at an outermost side, are arranged in a periphery of the arbitrary concave part 122, as illustrated in FIGS. 12A and 12B. The vertexes 121a of the four (4) convex parts 121 are arranged at equi-angular intervals (or pitch) of 90° with respect to the bottom 122a of the arbitrary concave part 122 located at a center of the four (4) convex parts 121, to form the regular tetragonal lattice shape.

The convex parts 121 may be arranged periodically in a quasi-tetragonal lattice shape, for example. The case in which “the convex parts 121 are periodically arranged in the quasi-tetragonal lattice shape” means that four (4) convex parts 121 are periodically arranged in a tetragonal lattice shape approximately conforming to the regular tetragonal lattice shape. The quasi-tetragonal lattice shape may have one or more lattices of the regular tetragonal lattice shape expanded in a predetermined direction or distorted. The distorted lattices of the regular tetragonal lattice shape may be continuously arranged in a linear shape, a curve shape, or a zigzag or wavy shape.

In this embodiment, an arbitrary convex part 121-1, excluding the convex part 121 located at the outermost side, and six (6) convex parts 121-2 through 121-7 having the distances from the arbitrary convex part 121-1 that amount to a smallest sum, are arranged to satisfy the following conditions (7) and (8), as illustrated in FIGS. 12A and 12B.

Condition (7): The connecting part 123 exists between the arbitrary convex part 121-1 and each of four (4) convex parts 121-2, 121-3, 121-5, and 121-6 amongst the six (6) convex parts 121-2 through 121-7; and

Condition (8): The concave part 122 exists between the arbitrary convex part 121-1 and each of two (2) remaining convex parts 121-4 and 121-7 amongst the six (6) convex parts 121-2 through 121-7.

The “distance” between two convex parts 121 refers to a distance between the vertexes 121a of the two convex parts 121. In a case in which a plurality of combinations exist for the six (6) convex parts 121 having the distances from the arbitrary convex part 121-1 that amount to the smallest sum, the conditions (7) and (8) described above stand for each of such combinations. In this example, there are six (6) combination for the six (6) convex parts 121 having the distances from the arbitrary convex part 121-1 that amount to the smallest sum, because there are four (4) convex parts 121 having the same shortest distance from the arbitrary convex part 121-1, and there are four (4) convex parts 121 having the same next shortest distance from the arbitrary convex part 121-1. The conditions (7) and (8) stand for each of these six (6) combinations.

In the case in which the conditions (7) and (8) stand, amongst three (3) directions that intersect at the arbitrary convex part 121-1 illustrated in FIG. 12B located at the center, the convex part 121 and the connecting part 123 are alternately arranged along two directions (directions J1 and J2), and the convex part 121 and the concave part 122 are alternately arranged along the remaining one direction (direction J3). A pitch P11 illustrated in FIGS. 13A and 13C with which the convex parts 121 are intermittently arranged in the directions J1 and J2 may be set to a length that is less than or equal to the wavelength of visible light. A pitch P12 illustrated in FIG. 13B with which the convex parts 121 are intermittently arranged in the direction J3 is greater than the pitch P11. The concave part 122 and the connecting part 123 are alternately arranged along a direction parallel to the direction J1, as illustrated in FIGS. 12A and 12B and FIG. 13C.

Accordingly, the direction in which the convex part 121 and the concave part 122 are alternately arranged, and the direction in which the convex part 121 and the connecting part 123 are alternately arranged, are different. For this reason, a height difference H11 illustrated in FIG. 13B between the vertex 121a of the convex part 121 and the bottom 122a of the concave part 122, and a height difference H12 illustrated in FIG. 13A between the vertex 121a of the convex part 121 and a predetermined part 123a of the connecting part 123 illustrated in FIG. 11, can be designed independently. In other words, the height difference H11 and the height difference H12 can be optimized independently. The predetermined part 123a of the connecting part 123 corresponds to a lowest part between the vertexes 121a of the convex parts 121, and corresponds to a highest part between the bottoms 122a of the concave parts 122.

The range of the pitch P11 may be set first in order to optimize the height difference H11 and the height difference H12. As described above, the pitch P11 is set to less than or equal to the wavelength of visible light, and may be 400 nm or less, for example, and may preferably be 300 nm or less. In addition, from the standpoint of productivity, the pitch P11 may be set to 50 nm or greater, for example, and may preferably be set to 100 nm or greater. Hence, the pitch P11 may be set in a range of 50 nm to 400 nm.

Next, a range of an aspect ratio of the concavo-convex parts 120 is set. The aspect ratio of the concavo-convex parts 120 is represented by a ratio H11/P11 of the height difference H11 between the vertex 121a of the convex part 121 and the bottom 122a of the concave part 122, and the pitch P11 of the convex parts 121. From the standpoint of low reflectivity of the anti-reflection structure 110, the aspect ratio H11/P11 may be 0.5 or greater, for example, and may preferably be 0.7 or greater, and may more preferably be 1 or greater. In addition, from the standpoint of productivity, the aspect ratio H11/P11 may be 4 or less, for example, and may preferably be 3 or less, and may more preferably be 2 or less. In a case in which the pitch of the convex parts 121 in the direction J1, the pitch of the convex parts 121 in the direction J2 are different, the aspect ratio may be obtained from the shortest pitch. Because the aspect ratio H11/P11 is in a range of 0.5 to 4, the height difference H11 may be in a range of 100 nm to 500 nm, for example.

Next, a ratio H12/H11 of the height difference H11 and the height difference H12 is set. The larger the ratio H12/H11, the lower the height of the predetermined part 123a of the connecting part 123 becomes, and the more improved the low reflectivity of the anti-reflection structure 110 becomes. The ratio H12/H11 may be 0.1 or greater, for example, and may preferably be 0.2 or greater, and may more preferably be 0.3 or greater. On the other hand, the smaller the ratio H12/H11, the more gradual the inclination becomes between the vertex 121a of the convex part 121 and the predetermined part 123a of the connecting part 123, as will be described later in more detail, and the thicker the transparent conductive layer 130 becomes, to make it easier for the current to flow. The ratio H12/H11 may be 0.9 or less, for example, and may preferably be 0.7 or less, and may more preferably be 0.5 or less. Because the ratio H12/H11 is in a range of 0.1 to 0.9, the height difference H12 may be in a range of 30 nm to 300 nm, for example.

According to this embodiment, the height difference H11 and the height difference H12 can ne optimized independently. For this reason, the aspect ratio H11/P11 and the ratio H12/H11 can be optimized independently, and it is possible to simultaneously achieve low reflectivity and high conductivity.

In this embodiment, the convex part 121 and the connecting part 123 are alternately arranged in the direction J1 and the direction J2 which are linear directions, and the convex part 121 and the concave part 122 are alternately arranged in the direction J3 which is a linear direction. However, as long as the conditions (7) and (8) described above stand, the present invention is not limited to such arrangements. For example, in a case in which the regular tetragonal lattice is arranged in a curved shape, the convex part 121 and the connecting part 123 may be alternately arranged along a predetermined curved direction.

In this embodiment, attention is drawn to the arrangement of the convex parts 121, similarly as in the case of the first embodiment, however, the attention may be drawn to the arrangement of the concave parts 122.

The transparent conductive layer 130 is formed on the concavo-convex parts 120 of the anti-reflection structure 110. The surface profile of the transparent conductive layer 130 follows the surface profile of the concavo-convex parts 120, and is approximately the same as the surface profile of the concavo-convex parts 120.

An average thickness of the transparent conductive layer 130 is in a range of 10 nm to 80 nm, for example. When the average thickness of the transparent conductive layer 130 is less than 10 nm, sufficiently high conductivity may not be obtained. On the other hand, when the average thickness of the transparent conductive layer 130 exceeds 80 nm, it becomes more difficult for the surface profile of the transparent conductive layer 130 to follow the surface profile of the concavo-convex parts 120.

The thickness of the transparent conductive layer 130 may be thicker at the part having the gradual inclination, and thinner at the part having the steep inclination. The thickness of the transparent conductive layer 130 may be the thickest at the vertex 121a of the convex part 121, and thinnest at the part between the vertex 121a of the convex part 121 and the bottom 122a of the concave part 122.

Between the vertex 121a of the convex part 121 and the bottom 122a of the concave part 122, the smaller the height difference H11 illustrated in FIG. 13B, the more gradual the inclination becomes and the thinner the thickness of the transparent conductive layer 130 becomes, to make it easier for the current to flow. On the other hand, when the height difference H11 is excessively small, it may be difficult to obtain a sufficiently low reflectivity.

The inclination is gradual at the predetermined part 123a of the connecting part 123, similarly as in the case of the vertex 121a of the convex part 121, and the transparent conductive layer 130 is thick at the predetermined part 123a. For this reason, the current easily flows in a net pattern along the direction J1 and the direction J2 in which the convex part 121 and the connecting part 123 are alternately arranged. Between the vertex 121a of the convex part 121 and the predetermined part 123a of the connecting part 123, the smaller the height difference H12 illustrated in FIG. 13A (that is, the smaller the ratio H12/H11), the more gradual the inclination becomes and the thicker the transparent conductive layer 130 becomes, to make it easier for the current to flow.

According to this embodiment, since the height difference H11 and the height difference H12 can be optimized independently as described above, it is possible to simultaneously achieve the low reflectivity and the high conductivity.

For example, the transparent conductive layer 130 may be made of a material such as ITO (In₂O₃—SnO₂: Indium Tin Oxide), SnO₂ (tin oxide), IZO (In₂O₃—ZnO: Indium Zinc Oxide), AZO (Aluminum-doped Zinc Oxide), FTO (Fluorine-doped Tin Oxide), GZO (Gallium-doped Zinc Oxide), or the like.

A production method for the laminated structure 102 described above may be the same as the production method for the laminated structure 2 in the first embodiment, and a description thereof will be omitted.

The present invention is of course not limited to the first and second embodiments described above, and various variations, modifications, and substitutions may be made without departing from the scope of the present invention.

For example, the laminated structure may include a low-reflection process layer having translucency, on a back surface of the anti-reflection structure that is opposite to the surface on which the moth eye type concavo-convex parts are formed. The low-reflection process layer may reduce the reflectivity by interference of light, or reduce the reflectivity by absorbing light. The low-reflection process layer may be made of an organic material and/or an inorganic material. A method of forming the low-reflection process layer may use dry coating or wet coating. The dry coating may include PVD, CVD, or the like. The wet coating may include die coating, spray coating, ink-jet coating, spin-coating, or the like. In a case in which the anti-reflection structure is used in a touchscreen panel, the low-reflection process layer may be arranged on an outer side of the touchscreen panel, and the moth eye type concavo-convex parts may be arranged on an inner side of the touchscreen panel.

In addition, the laminated structure may include a protection layer having translucency, formed on the transparent conductive layer. The protection layer may absorb the concavo-convex profile of the transparent conductive layer, to smoothen the surface of the laminated structure. The protection layer may be made of an organic material and/or an inorganic material. For example, the protection layer may be formed by a dielectric layer made of SiO₂ or the like.

Although the convex part of the embodiments described above is formed in a narrowing shape towards its vertex, the convex part may have a flat vertex part. In this case, the “distance” between two convex parts refers to the distance between centers of the flat vertex parts of the two convex parts. Similarly, although the concave part of the embodiments described above is formed in a narrowing shape towards its bottom, the concave part may have a flat bottom part.

Next, a description will be given of applications of the laminated structure in the embodiments described above, by referring to FIGS. 14 through 16.

FIG. 14 is a cross sectional view illustrating an example of a display device using the laminated structure. In FIG. 14, a display device 140 includes a metal electrode layer 141, a light emitting layer 142, a transparent electrode layer 143, and a transparent substrate 144 that are laminated. For example, the light emitting layer 142 may be formed by an OLED (Organic Light Emitting Diode) or an OEL (Organic Electro-Luminescence) element. For example, the transparent substrate 144 may be made of glass or the like. The transparent electrode layer 143 may be formed by the laminated structure 2 illustrated in FIG. 1 or the laminated structure 102 illustrated in FIG. 10, for example. By using the laminated structure 2 or 102 for the transparent electrode layer 143, reflection at an interface between the transparent substrate 144 and the transparent electrode layer 143 can be reduced, and an efficiency with which light is extracted can be improved, to thereby improve a luminous efficacy of the display device 140.

FIG. 15 is a cross sectional view illustrating an example of an illumination device using the laminated structure. In FIG. 15, an illumination device 150 includes a metal electrode layer 151, a light emitting layer 152 formed by an OLED or OEL element, a transparent electrode layer 153, and a transparent substrate 154 made of glass or the like, that are laminated. The transparent electrode layer 153 may be formed by the laminated structure 2 illustrated in FIG. 1, or the laminated structure 102 illustrated in FIG. 10, for example. By using the laminated structure 2 or 102 for the transparent electrode layer 153, reflection at an interface between the transparent substrate 154 and the transparent electrode layer 153 can be reduced, and an efficiency with which light is extracted can be improved, to thereby improve a luminous efficacy of the illumination device 150.

FIG. 16 is a cross sectional view illustrating an example of a solar cell using the laminated structure. In FIG. 16, a solar cell 160 includes a metal electrode layer 161, a P-type semiconductor layer 162-1 formed by a P-type silicon, for example, an N-type semiconductor layer 162-2 formed by an N-type silicon, for example, a transparent electrode layer 163, and a transparent substrate 164 made of glass or the like, that are laminated. The P-type semiconductor layer 162-1 and the N-type semiconductor layer 162-2 are examples of a power generating layer. The transparent electrode layer 163 may be formed by the laminated structure 2 illustrated in FIG. 1, or the laminated structure 102 illustrated in FIG. 10, for example. By using the laminated structure 2 or 102 for the transparent electrode layer 163, reflection at an interface between the transparent substrate 164 and the transparent electrode layer 163 can be reduced, and an efficiency with which light is input to the solar cell 160 can be improved, to thereby improve a cell efficiency or power generating efficiency of the solar cell 160.

A solar panel (not illustrated), which is an example of a solar power generator, may have a structure in which a plurality of solar cells 160, such as that illustrated in FIG. 16, are arranged in a matrix arrangement, for example. In this case, by using the laminated structure 2 or 102 for the transparent electrode layer 163 of each solar cell 160, the reflection at the interface between the transparent substrate 154 and the transparent electrode layer 153 can be reduced, and the efficiency with which light is input to each solar cell 160 can be improved, to thereby improve the cell efficiency or power generating efficiency of the solar panel.

### Practical Examples

Next, a description will be given of practical examples of the embodiments, however, the present invention is of course not limited to such practical examples.

### Practical Example Emb1

In a practical example Emb1, the anti-reflection structure having the periodic concavo-convex parts on the surface thereof is produced according to the method described above in conjunction with FIGS. 6A through 6C, FIGS. 7A through 7C, and FIGS. 9A and 9B, and the laminated structure is produced by forming the transparent conductive layer on the concavo-convex parts of the anti-reflection structure. The convex parts of the concavo-convex parts of the anti-reflection structure are arranged in the regular hexagonal lattice shape.

The die of the stamper is produced by forming the resist layer made of an acrylic resin on the base that is formed by a glass substrate, exposing the interference fringes two times on the resist layer, and developing the resist layer. An ArF excimer (wavelength of 193 nm) is used for the light source of the interference fringes, and an intersecting angle of the interference fringes exposed by the first exposure and the interference fringes exposed by the second exposure is 60°. The produced die has the concavo-convex parts on the surface thereof.

The dimensions of the shape of the concavo-convex parts of the die are measured by an AFM (L-trace manufactured by Seiko Instruments Inc.). The measured height difference between the vertex of the convex part and the bottom of the concave part is 250 nm, the measured height difference between the vertex of the convex part and the connecting part is 125 nm, and a shorted pitch of the vertexes of the convex parts is 250 nm.

The stamper is produced by forming an Ni layer on the concavo-convex parts of the die by electroforming, and separating the Ni layer from the die. The dimensions of the surface of the stamper are measured using the AFM. The measured dimensions indicate that the concavo-convex parts on the surface of the stamper have the reversed shape of the concavo-convex parts of the die.

The anti-reflection structure is produced by spin-coating an acrylic resin, which is an example of a photopolymer, on an extruded PET (Poly-Ethylene Terephthalate) film extruded in two directions, which is an example of the base, irradiating UV (Ultra-Violet) light in a state in which the concavo-convex parts of the stamper are pressed against the surface of the spin-coated layer, and curing the spin-coated layer. The dimensions of the surface of the resin layer formed by UV-curing the spin-coated layer are measured using the AFM. The measured dimensions indicate that the concavo-convex parts on the surface of the resin layer have the reversed shape of the concavo-convex parts of the stamper. The concavo-convex parts of the resin layer have dimensions and shapes that are approximately the same as those of the concavo-convex parts of the die, and the height difference H1 illustrated in FIG. 4A is 250 nm, the height difference H2 illustrated in FIG. 4B is 125 nm, and the pitch P1 illustrated in FIGS. 4A, 4B, and 4D is 250 nm.

The laminated structure is produced by forming the transparent conductive layer on the concavo-convex parts of the anti-reflection structure. An ITO layer formed by vacuum sputtering is used for the transparent conductive layer. The ITO layer has an average thickness of 20 nm, 40 nm, or 60 nm. The average thickness of the ITO layer corresponds to the thickness of the transparent conductive layer that is formed on the surface of a flat plate part that includes no concavo-convex structure, when forming the ITO layer on the concavo-convex parts of the anti-reflection structure.

A surface resistivity of the laminated structure on the side of the transparent conductive layer is measured by a contactless conductivity analyzer (717 Conductance Monitor manufactured by Delcom Instruments, Inc.). FIG. 18 is a diagram illustrating measured results of the surface resistivity in the practical example Emb1 and a comparison example Cmp1. In FIG. 18, the ordinate indicates the thickness (nm) of the transparent conductive layer, and the abscissa indicates the surface resistivity (Ω/□).

The reflectivity for a case in which visible light is irradiated on the surface of the transparent conductive layer having the average thickness of 60 nm is measured by a spectral analyzer (ARM-500N manufactured by JASCO Corporation). FIG. 19 is a diagram illustrating measured results of the reflectivities in the practical example Emb1 and the comparison example Cmp1. In FIG. 19, the ordinate indicates the reflectivity (%), and the abscissa indicates the wavelength (nm) of incident light. In addition, in FIG. 19, L1 denotes the measured results for the practical example Emb1, and L11 denotes the measured results for the comparison example Cmp1 to be described later.

### Comparison Example Cmp1

In the comparison example Cmp1, a conventional anti-reflection structure having concavo-convex parts on a surface thereof is produced, and a laminated structure is produced by forming a transparent conductive layer on the concavo-convex parts of the anti-reflection structure. The convex parts of the concavo-convex parts of the anti-reflection structure are periodically arranged in the regular hexagonal lattice shape.

A die of a stamper is produced by forming a resist layer made of an acrylic resin on a silicon substrate which is an example of a base, exposing the resist layer by EB lithography, and developing the resist layer. The produced die includes concavo-convex parts on a surface thereof, and these concavo-convex parts have cone-shaped projections 94 (only five (5) cone-shaped projections illustrated in FIG. 17) arranged on a plane 92, as illustrated in FIG. 17. FIG. 17 is a diagram for explaining a method of creating an analyzing model in a first comparison example.

In each cone-shaped projection 94, an edge part between a vertex surface and a side surface of a circular truncated cone is rounded by chamfering, and a tip end part is formed by a part of a spherical surface. Lower parts of the cone-shaped projections 94 partially overlap, so that outer peripheries of bottom surfaces 94a of three (3) mutually adjacent cone-shaped projections 94 intersect at a single point on the plane 92.

The dimensions of the shape of the concavo-convex parts of the die are measured by the AFM (L-trace manufactured by Seiko Instruments Inc.). A measured height H21 of the cone-shaped projection 94 is 450 nm, and a measured pitch P21 of vertexes 94b of two adjacent cone-shaped projections 94 is 300 nm.

A stamper is produced by forming an Ni layer on the concavo-convex parts of the die by electroforming, and separating the Ni layer from the die. The dimensions of the surface of the stamper are measured using the AFM. The measured dimensions indicate that the concavo-convex parts on the surface of the stamper have the reversed shape of the concavo-convex parts of the die.

An anti-reflection structure is produced by spin-coating a UV-curing acrylic resin on a glass substrate which is an example of a base, irradiating UV light in a state in which the concavo-convex parts of the stamper are pressed against the surface of the spin-coated layer, and curing the spin-coated layer. The dimensions of the surface of the resin layer formed by UV-curing the spin-coated layer are measured using the AFM. The measured dimensions indicate that the concavo-convex parts on the surface of the resin layer have the reversed shape of the concavo-convex parts of the stamper. The concavo-convex parts of the resin layer have dimensions and shapes that are approximately the same as those of the concavo-convex parts of the die, and the height H21 is 450 nm and the pitch P21 is 300 nm.

A laminated structure is produced by forming the transparent conductive layer on the concavo-convex parts of the anti-reflection structure. An ITO layer formed by vacuum sputtering is used for the transparent conductive layer. The ITO layer has an average thickness of 20 nm, 40 nm, or 60 nm.

A surface resistivity and a reflectivity of the laminated structure is measured for the case in which the average thickness of the transparent conductive layer is 60 nm, in a manner similar to making the measurements for the laminated structure of the practical example Emb1. The measured results for the comparison example Cmp1 are illustrated in FIGS. 18 and 19.

From FIGS. 18 and 19, it is confirmed that, unlike the structure of the comparison example Cmp1, the structure of the practical example Emb1 can obtain both low reflectivity and high conductivity. In the comparison example Cmp1, the convex parts of the concavo-convex parts of the anti-reflection structure do not satisfy the conditions (1) and (2) described above, and the surface resistivity is high. It may be regarded that the high resistivity of the comparison example Cmp1 is caused by the steep inclination between the mutually adjacent convex parts of the anti-reflection structure.

According to the embodiments and examples thereof, the laminated structure and the laminated structure production method can simultaneously achieve low reflectivity and high conductivity.

The laminated structure and the laminated structure production method may be suitably applied to display devices, illumination devices, solar cells, solar panels, and the like.

Although the embodiments are numbered with, for example, “first,” “second,” . . . , the ordinal numbers do not imply priorities of the embodiments. Many other variations and modifications will be apparent to those skilled in the art.

Further, the present invention is not limited to the embodiments are examples described above, and various variations and modifications may be made without departing from the object of the present invention.

What is claimed is:

1. A laminated structure comprising:
an anti-reflection structure having periodic concavo-convex parts on a surface thereof; and
a transparent conductive layer formed on the concavo-convex parts,
wherein an arbitrary convex part, excluding a convex part located at an outermost side, and six convex parts having distances from the arbitrary convex part that amount to a smallest sum, are arranged to satisfy conditions (1) and (2),
wherein the condition (1) requires a connecting part to exist between the arbitrary convex part and each of four convex parts amongst the six convex parts, and
wherein the condition (2) requires a concave part to exist between the arbitrary convex part and each of two remaining convex parts amongst the six convex parts.

2. The laminated structure as claimed in claim 1, wherein amongst three directions that intersect at the arbitrary convex part located at a center, the convex part and the connecting part are alternately arranged along two of the three directions, and the convex part and the concave part are alternately arranged along a remaining one of the three directions.

3. The laminated structure as claimed in claim 1, wherein the convex parts are periodically arranged in a regular hexagonal lattice shape.

4. The laminated structure as claimed in claim 1, wherein the convex parts are periodically arranged in a regular tetragonal lattice shape.

5. A display device comprising:
a metal electrode layer, a light emitting layer, a transparent electrode layer, and a transparent substrate that are laminated,
wherein the transparent electrode layer is formed by the stacked structure as claimed in claim 1.

6. An illumination device comprising:
a metal electrode layer, a light emitting layer, a transparent electrode layer, and a transparent substrate that are laminated,
wherein the transparent electrode layer is formed by the stacked structure as claimed in claim 1.

7. A solar cell comprising:
a metal electrode layer, a power generating layer, a transparent electrode layer, and a transparent substrate that are laminated,
wherein the transparent electrode layer is formed by the laminated structure as claimed in claim 1.

8. A laminated structure production method, comprising:
producing an anti-reflection structure having periodic concavo-convex parts on a surface thereof, by using a die having periodic concavo-convex parts on a surface thereof; and
forming a transparent conductive electrode on the concavo-convex parts of the anti-reflection structure,
wherein an arbitrary convex part, excluding a convex part located at an outermost side, and six convex parts having distances from the arbitrary convex part that amount to a smallest sum, of the periodic concavo-convex parts of the die, are arranged to satisfy conditions (1) and (2),
wherein the condition (1) requires a connecting part to exist between the arbitrary convex part and each of four convex parts amongst the six convex parts, and
wherein the condition (2) requires a concave part to exist between the arbitrary convex part and each of two remaining convex parts amongst the six convex parts.

9. The laminated structure production method as claimed in claim 8, wherein amongst three directions that intersect at the arbitrary convex part located at a center, the convex part and the connecting part are alternately arranged along two of the three directions, and the convex part and the concave part are alternately arranged along a remaining one of the three directions.

10. The laminated structure production method as claimed in claim 8, further comprising:
producing the die,
wherein the producing the die includes
forming a resist on a base;
exposing, on a surface of the resist layer, first interference fringes having a light intensity that changes in a first direction;
exposing, on the surface of the resist layer, second interference fringes having a light intensity that changes in a second direction intersecting the first direction; and
developing the resist layer after exposing the first and second interference fringes.

11. The laminated structure production method as claimed in claim 10, wherein an angle formed by the first direction and the second direction is 60°.

12. The laminated structure production method as claimed in claim 10, wherein an angle formed by the first direction and the second direction is 90°.
